(19) United States
(12) Patent Application Publication
(10) Pub. No.: US 2017/0353020 A1
(43) Pub. Date: Dec. 7, 2017

(54) CIRCUIT ASSEMBLY AND ELECTRICAL JUNCTION BOX

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-shi, Osaka (JP)

(72) Inventors: Takahiro Yamashita, Yokkaichi, Mie (JP); Yoshikazu Sasaki, Yokkaichi, Mie (JP); Takehito Kobayashi, Yokkaichi, Mie (JP); Yukinori Kita, Yokkaichi, Mie (JP)

(21) Appl. No.: 15/535,225

(22) PCT Filed: Dec. 4, 2015
(86) PCT No.: PCT/JP2015/084121

§ 371 Date: Jun. 12, 2017

(30) Foreign Application Priority Data
Dec. 22, 2014 (JP) 2014-258909

(51) Int. Cl. H02G 3/03; H02G 3/08; B60R 16/03; H02G 3/16; H05K 7/20; H05K 5/00

(52) U.S. Cl. CPC H02G 3/03; H05K 7/20409; H05K 5/0052; B60R 16/03; H02G 3/16; H02G 3/081; H05K 5/0008

(57) ABSTRACT

A circuit assembly is provided with a circuit unit that includes an electrically conducting path on which electronic components are mounted, a heat discharging member that is placed on the circuit unit, and is configured to discharge heat of the circuit unit, and a spacer that is disposed between the circuit unit and the heat discharging member. The spacer is provided with a main portion that is disposed between the circuit unit and the heat discharging member, and accommodating portions that accommodate a part of the circuit unit.

### CROSS-REFERENCE TO RELATED APPLICATIONS

This application is the U.S. national stage of PCT/JP2015/084121 filed Dec. 4, 2015, which claims priority of Japanese Patent Application No. JP 2014-258909 filed Dec. 22, 2014.

### TECHNICAL FIELD

The present invention relates to a circuit assembly and an electrical junction box.

### BACKGROUND

Conventionally, circuit assemblies in which a circuit board and a heat discharging member that discharges heat of the circuit board to the outside are stacked on each other are known. In this type of circuit assemblies, the circuit board is adhered to the heat discharging member with an adhesive agent. JP 2005-151617A discloses a circuit assembly in which a sheet-shaped component obtained by braiding insolation fibers into a sheet is laid on an adhesive agent that is applied to a heat discharging member so that the adhesive agent passes substantially uniformly through the entire sheet-shaped component. A circuit structure is laid on this sheet-shaped component and is pressed towards the heat discharging member side, thus fixing it to the heat discharging member.

Meanwhile, in JP 2005-151617A in which the circuit structure is pressed towards the heat discharging member side when being fixed to the heat discharging plate, if the distance between a circuit board and the heat discharging member is not kept constant, there is a risk that the pressure that acts on the adhesive agent via the circuit structure when it is pressed may become non-uniform, and defects may occur such as locations where adhesion with the adhesive agent is insufficient. On the other hand, if a jig is used to keep the distance between the circuit board and the heat discharging member constant, there is the problem that a cost will be incurred for the jig.

JP 2014-82844A discloses an electrical junction box provided with a circuit unit on which electronic components are mounted, a heat discharging member that discharges heat of the circuit unit, and a frame-shaped member that is disposed on the heat discharging member and accommodates the circuit unit. The frame-shaped member has compartments into which the electronic components are accommodated, and holds the electronic components in their positions.

Here, if a spacer for keeping the distance between the circuit board and the heat discharging member constant is provided between the circuit structure and the heat discharging member in order to solve the problems of JP 2005-151617A, it is not preferable to provide, in addition to the spacer, a frame-shaped member for holding electronic components in positions as disclosed in JP 2014-82844A because this will lead to an increase in the number of components and complication of the structure.

The present invention was made in view of the above-described circumstances, and it is an object thereof to hold a part of a circuit unit at a predetermined position while keeping the distance between a circuit board and a heat discharging member constant, with a simple configuration.

### SUMMARY

According to the present invention, a circuit assembly includes: a circuit unit that includes an electrically conducting path on which electronic components are mounted; a heat discharging member that is placed on the circuit unit, and is configured to discharge heat of the circuit unit; and a spacer that is disposed between the circuit unit and the heat discharging member, wherein the spacer is provided with a main portion that is disposed between the circuit unit and the heat discharging member, and an accommodating portion that accommodates a part of the circuit unit.

According to the present invention, since the main portion of the spacer is disposed between the circuit unit and the heat discharging member, it is possible to keep the distance between the circuit unit and the heat discharging member constant without using a jig. Furthermore, since the accommodating portion of the spacer accommodates a part of the circuit unit, it is possible to hold that part of the circuit unit at a predetermined position using the structure of the spacer, instead of providing a separate member for accommodating a part of the circuit unit. Accordingly, it is possible to hold a part of the circuit unit at a predetermined position while keeping the distance between the circuit board and the heat discharging member constant, with a simple configuration.

The embodiments of the present invention may have following aspects:

The main portion and the accommodating portion may be molded in one piece using a resin.

With this, it is possible to simplify the configuration compared to a case where, for example, a separate accommodating portion is fixed to the main portion to form a spacer.

The accommodating portion may accommodate an external connection terminal of the circuit unit.

The accommodating portion may accommodate a coil of the circuit unit.

The accommodating portion may accommodate a nut of the circuit unit.

The main portion may be provided with a through hole that is formed through the main portion, and a heat transmission portion that is arranged in the through hole, and is configured to transmit heat of the circuit unit to the heat discharging member.

With this, the heat transmission portion allows heat of the circuit unit to be discharged from the heat discharging member.

The circuit unit and the heat discharging member may be fastened to each other with screws.

With this, the circuit unit and the heat discharging member can be fixed to each other firmly with the screws, while the spacer receives a force acting when the circuit unit and the heat discharging member are fastened to each other with the screws.

An electrical junction box is provided with the above-described circuit assembly.

According to the present invention, it is possible to hold a part of a circuit unit at a predetermined position while keeping the distance between a circuit board and a heat discharging member constant, with a simple configuration.

### BRIEF DESCRIPTION OF DRAWINGS

FIG. 1 is a perspective view illustrating an electrical junction box according to Embodiment 1.

FIG. 2 is a plan view illustrating the electrical junction box.

FIG. 3 is a cross-sectional view taken along a line A-A in FIG. 2.

FIG. 4 is a cross-sectional view taken along a line B-B in FIG. 2.

FIG. 5 is a plan view illustrating a circuit board.

FIG. 6 is a perspective view illustrating a spacer.

FIG. 7 is a plan view illustrating the spacer.

FIG. 8 is a front view illustrating the spacer.

FIG. 9 is a side view illustrating the spacer.

FIG. 10 is a rear view illustrating the spacer.

FIG. 11 is a bottom view illustrating the spacer.

FIG. 12 is a plan view illustrating an auxiliary member.

FIG. 13 is a side view illustrating the auxiliary member.

FIG. 14 is a perspective view illustrating a heat discharging member.

FIG. 15 is a plan view illustrating the heat discharging member.

FIG. 16 is a plan view illustrating a state in which the spacer is mounted on the heat discharging member.

FIG. 17 is a plan view illustrating a state in which the circuit board is mounted starting from the state of FIG. 16.

### DETAILED DESCRIPTION OF THE PREFERRED EMBODIMENTS

### Embodiment 1

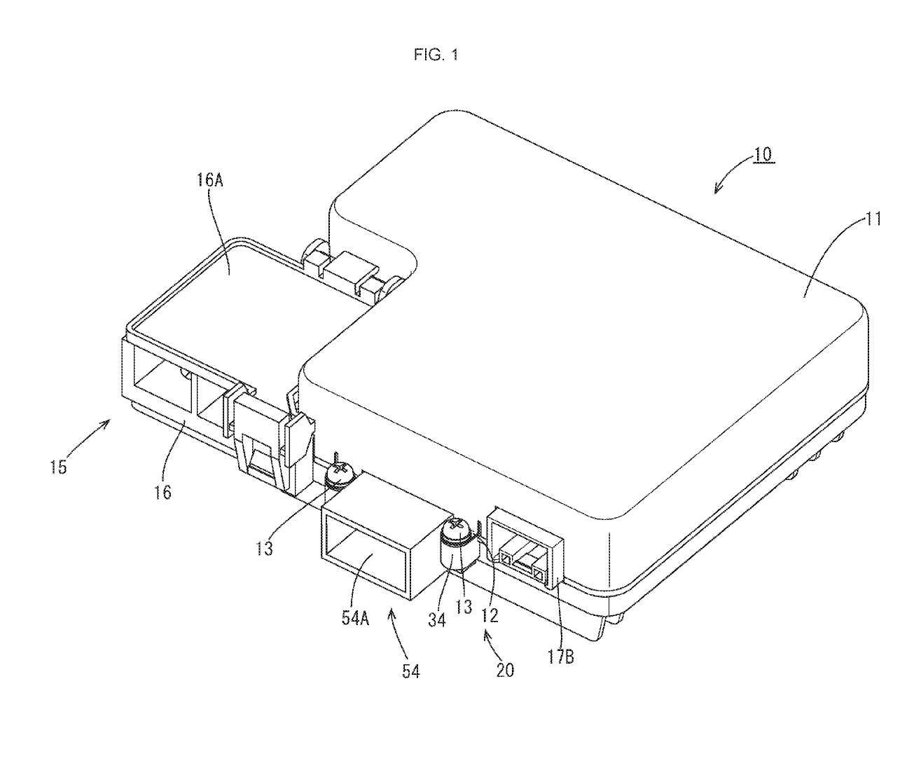

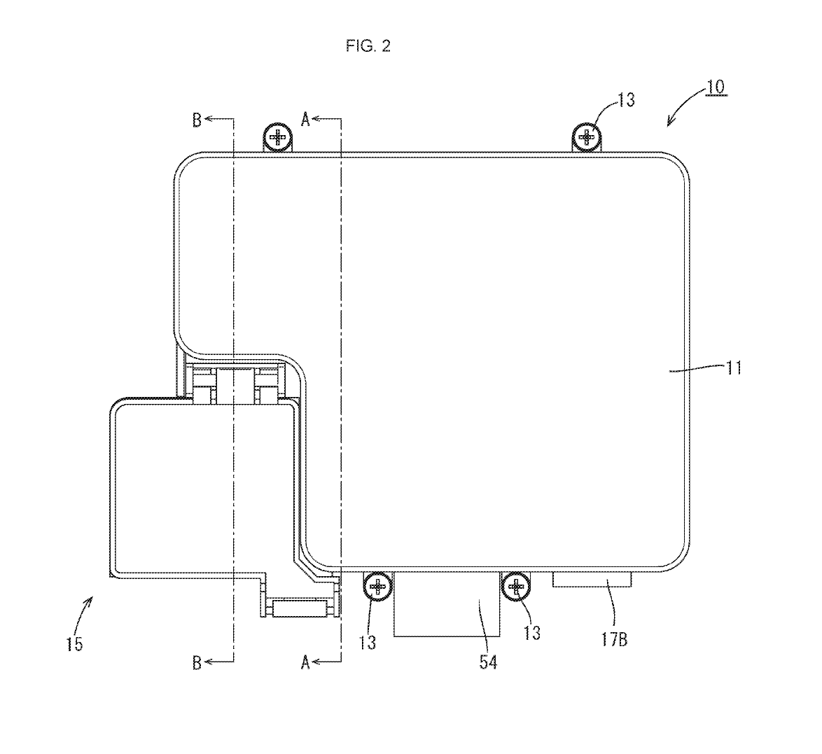

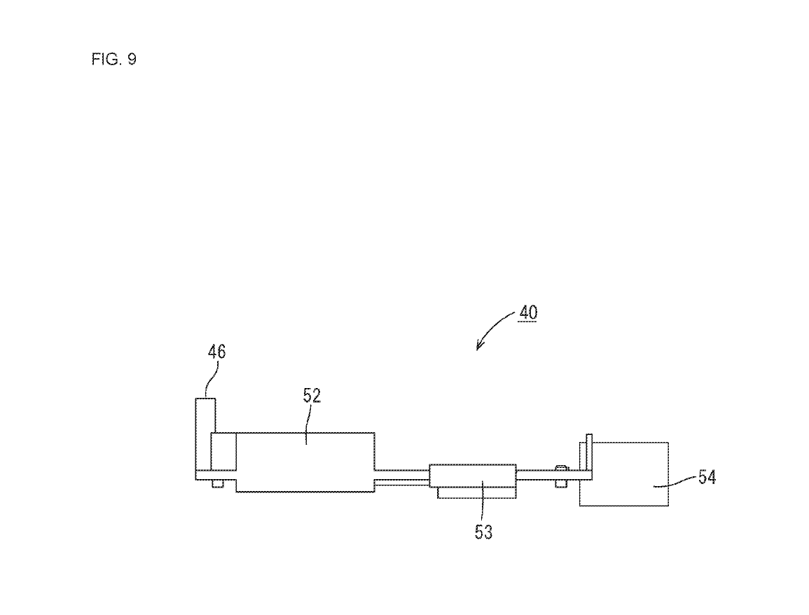

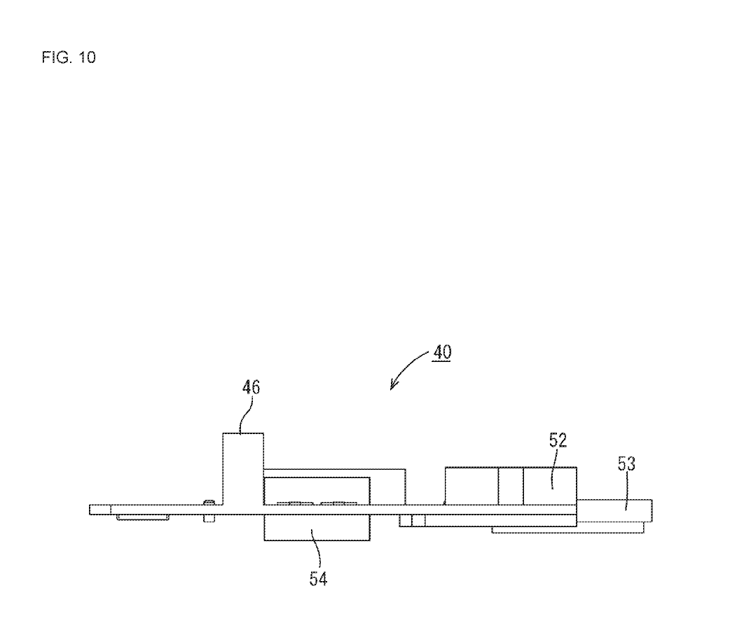

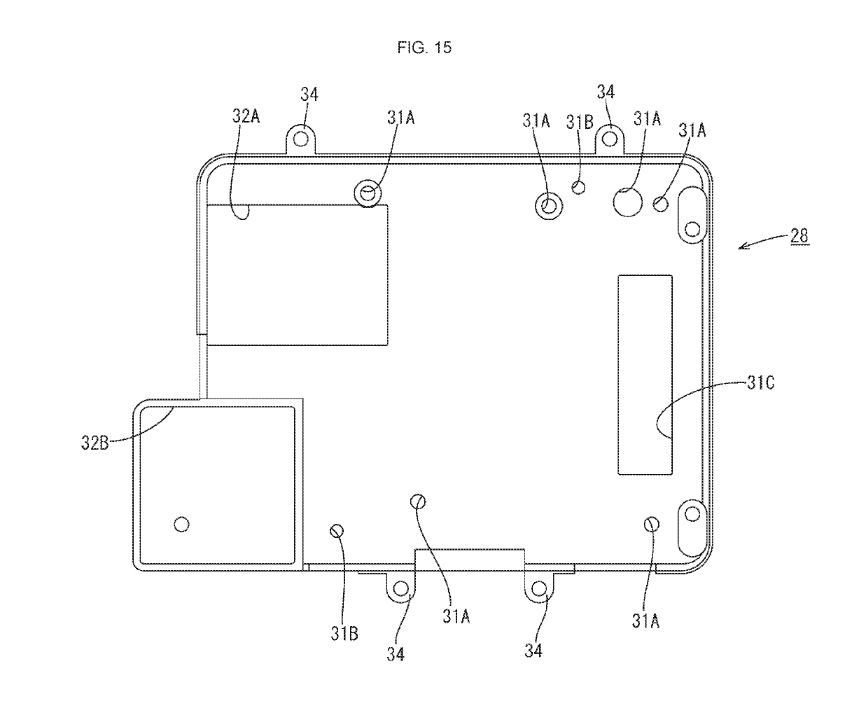

Hereinafter, Embodiment 1 will be described with reference to FIGS. 1 to 17.

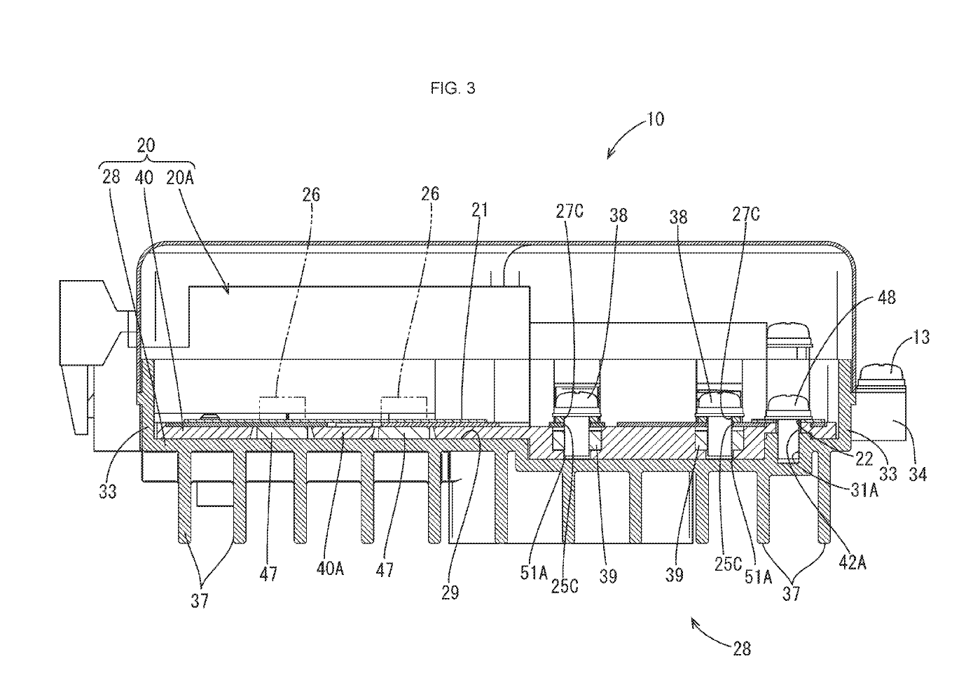

An electrical junction box 10 is arranged on, for example, an electric power supplying path between a power supply such as a battery of a vehicle, and loads including an in-car electric component, such as a lamp or a wiper, and a motor, and can be used, for example, for a DC-DC converter, an inverter, or the like. In the description below, “upward” and “downward” are based on the directions in FIG. 3.

### Electrical Junction Box 10

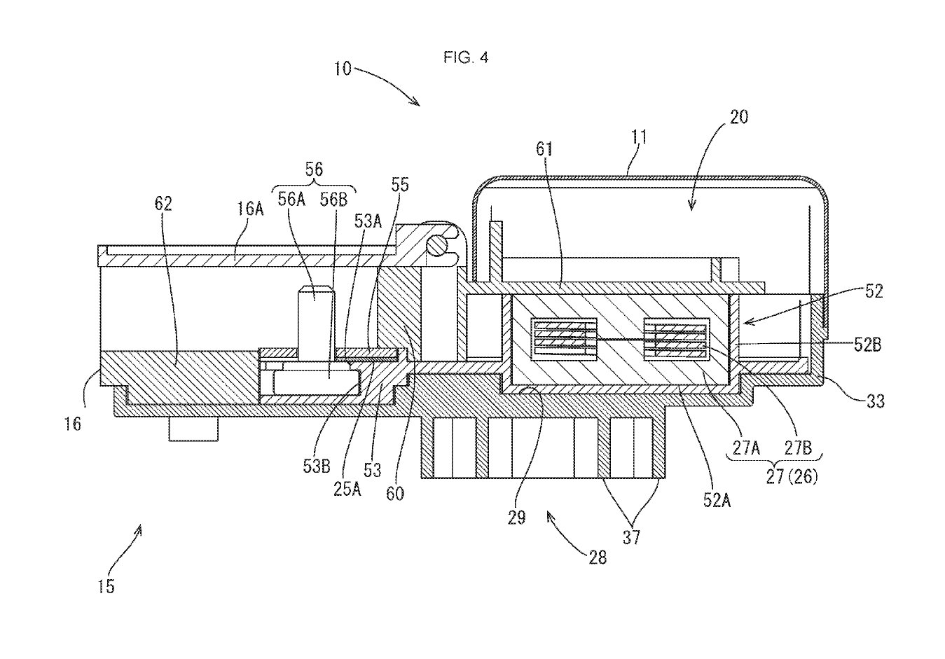

As shown in FIGS. 1 and 4, the electrical junction box 10 is provided with a circuit assembly 20, and a shield cover 11 that covers the upper side of the circuit assembly 20. The shield cover 11 is made of plate-shaped metal such as aluminum that was subjected to a punching process and a bending process, or a casting process, and is provided with, at a lower end thereof, fixation pieces 12 that are bent in an L-shape. As a result of the fixation pieces 12 being fastened to boss parts 34 of a heat discharging member 28 with screws 13, the shield cover 11 is connected to the ground via the heat discharging member 28. An external connection part 15 is formed in a corner of the electrical junction box 10. The external connection part 15 accommodates, in the inside of a box portion 16, a stud bolt 56 for connecting to a terminal at a terminal end of an external electric wire that is not shown, the box portion 16 being made of a synthetic resin and being able to be opened and closed with a cover portion 16A.

### Circuit Assembly 20

As shown in FIG. 3, the circuit assembly 20 is provided with: a circuit unit 20A; the heat discharging member 28 that is placed on the circuit unit 20A and discharges heat of the circuit unit 20A; and a spacer 40 that is disposed between the circuit unit 20A and the heat discharging member 28.

### Circuit Unit 20A

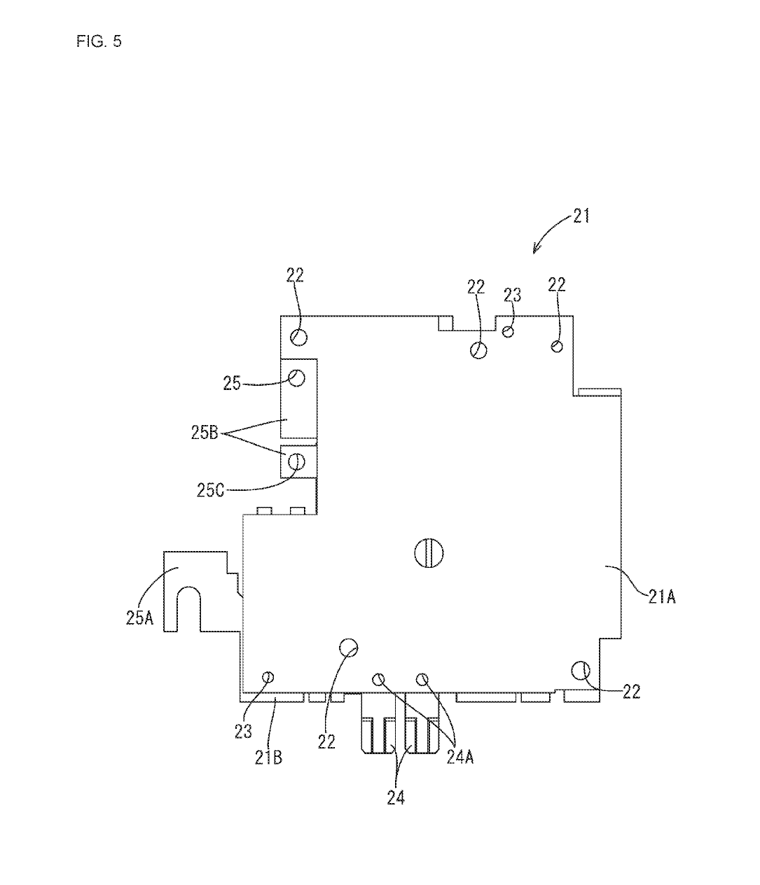

The circuit unit 20A is provided with a circuit board 21 with an electrically conducting path, and electronic components 26 that are mounted on the electrically conducting path. The circuit board 21 is rectangular as shown in FIG. 5, and has, at positions close to the peripheral edge of the circuit board 21, a plurality of screw holes 22 for screwing screws 48 and a plurality of positioning holes 23 for positioning the circuit board 21 with respect to the spacer 40. The screw holes 22 and the positioning holes 23 are formed through the circuit board 21. This circuit board 21 is made by adhering a printed board 21A and a busbar board 21B with each other using an adhesive member (such as an adhesive sheet or an adhesive agent, for example). The printed board 21A is rectangular, and is obtained such that an electrically conducting path (not shown) made of a copper foil is formed on an insulating plate made of an insulating material using printed wiring. The busbar board 21B is constituted by a plurality of busbars that are made of metal plate materials such as copper or a copper alloy that have a shape conforming to the shape of the electrically conducting path, and are arranged at intervals to each other. The busbar board 21B includes, at its ends, connector terminals 24 (an example of an “external connection terminal”), a terminal portion 25A that is connected to the stud bolt 56 (an example of the “external connection terminal”) that is a part of the circuit unit 20A, and terminal portions 25B that are connected to ends of a coil wire 27B of a coil 27. A part of the terminal portion 25A is cut out for the stud bolt 56 to be inserted thereinto. The terminal portions 25B are provided with passage holes 25C for connecting the coil wire 27B by bolting.

The electronic components 26 are mounted on the circuit board 21 as shown in FIGS. 3 and 4, and include a high heat-generating component such as a switching element (for example, an FET (Field Effect Transistor)), a resistor, or the coil 27, and a low heat-generating component such as a capacitor that generates relatively less heat. The high heat-generating component has a main portion that generates heat, and a plurality of lead terminals that are drawn from the main portion. The lead terminals of the electronic components 26 are soldered to the electrically conducting path of the printed board 21A, and the busbar board 21B.

The coil 27 includes a magnetic material core 27A and the coil wire 27B. The coil wire 27B is obtained by winding a flat rectangular copper wire that has a rectangular cross section in a so-called edgewise manner. The coil wire 27B has, at the respective ends thereof, passage holes 27C that are formed through the coil wire 27B, and are electrically connected to the terminal portions 25B by inserting the shaft portions of screws 38 (bolts) into the passage holes 25C and 27C, and fastening nuts 39 to the screws 38.

### Heat Discharging Member 28

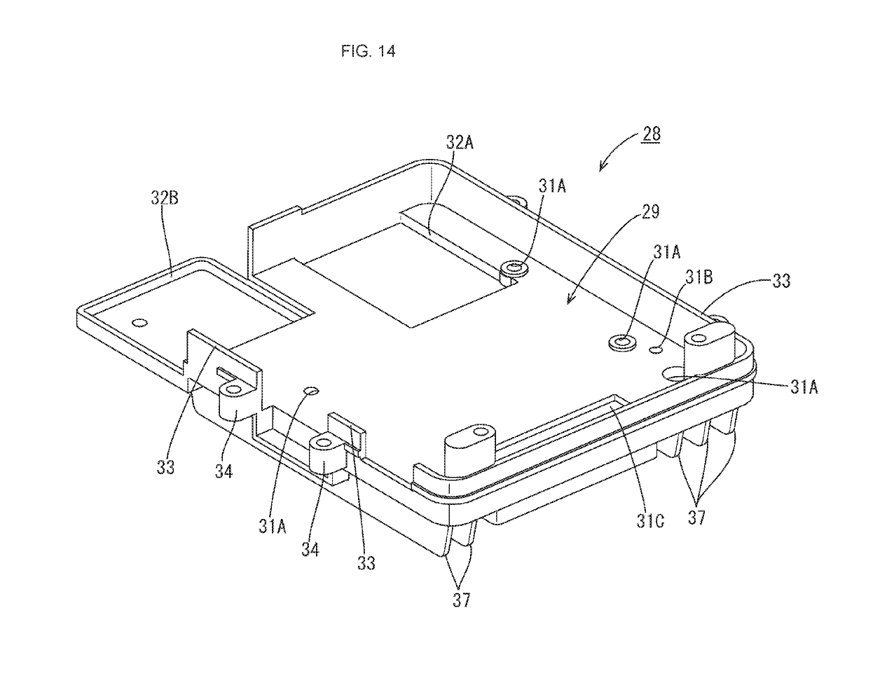

The heat discharging member 28 is made of a metal material such as aluminum or an aluminum alloy that is molded using aluminum die casting for example, or another material. As shown in FIG. 14, the heat discharging member 28 is provided with a mounting portion 29 on which the spacer 40 is mounted, a peripheral wall portion 33 that protrudes upward from the peripheral edge of the mounting portion 29, and heat discharging fins 37 that are provided on the bottom side of the mounting portion 29.

The mounting portion 29 has a flat upper surface. The mounting portion 29 has, at positions on the edge side of the mounting portion 29, a plurality of screw holes 31A for screwing screws, a plurality of positioning holes 31B for positioning the spacer 40, and a clearance recess 31C. An end of a terminal (not shown) that is inserted into a through hole of the circuit board 21 is arranged in the clearance recess 31C. The mounting portion 29 has recesses 32A and 32B at positions that correspond to the coil 27 (not shown) and the stud bolt 56.

In a state in which the spacer 40 and the circuit board 21 are stacked on the mounting portion 29, the peripheral wall portion 33 is higher than the upper end of the circuit board 21. The peripheral wall portion 33 is divided at positions that correspond to connector portions 17B and 54, and the connector terminals 24. The boss parts 34 with a screw hole protrude outward from the outer side of the peripheral wall portion 33.

### Spacer 40

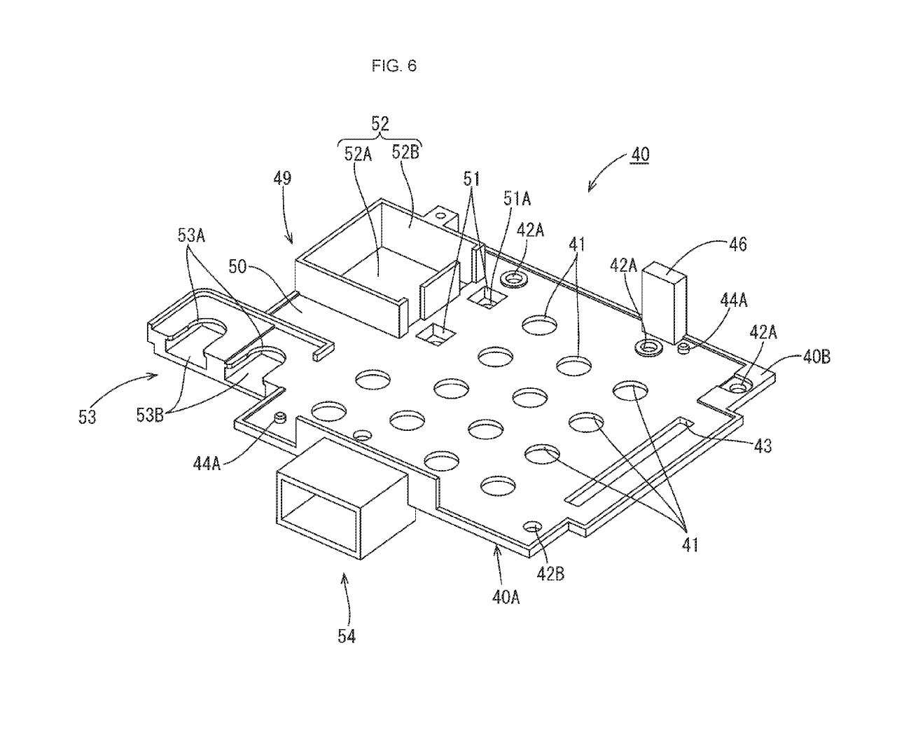

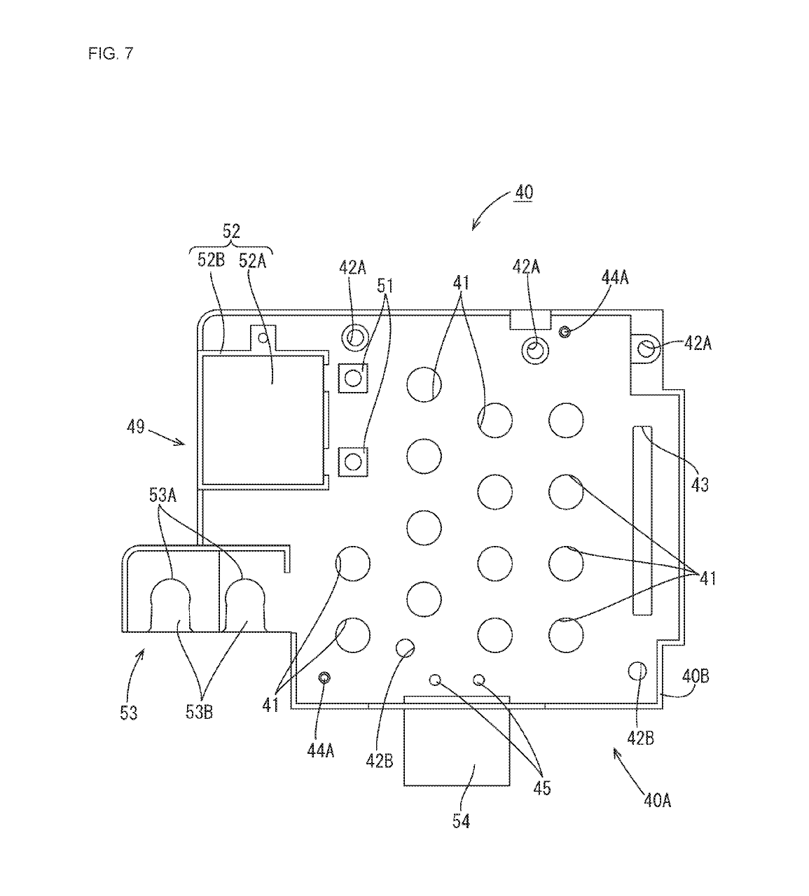

The spacer 40 is a rectangular insulating plate having such a thickness that it is not easily bent, and is mounted on the entire upper surface of the heat discharging member 28. As shown in FIGS. 6 and 7, the spacer 40 is provided with a plate-shaped main portion 40A in a region with which the circuit board 21 is to overlap (region on the right side of FIG. 7), and an extended portion 49 that is contiguous with the main portion 40A, and extends to a region with which the circuit board 21 is not to overlap (region on the left side of FIG. 7).

The main portion 40A is provided with a plurality of (fourteen in the present embodiment) through holes 41 that are formed through the main portion 40A, screw passage holes 42A and 42B through which the shaft portions of the screws 48 pass, a terminal passage hole 43, positioning projections 44A and 44B, and engaging projections 45.

Each through hole 41 is circular in the shape of a true circle, and is formed through the spacer 40 so as to be able to accommodate a heat transmission portion 47 that transmits heat of the circuit unit 20A to the heat discharging member 28. Two or four through holes 41 are lined up in a plurality of lines arranged at equal intervals (intervals in a left-right direction of FIG. 7), and in each of the lines, the through holes 41 are lined up at equal intervals (intervals in the up-down direction of FIG. 7). The through holes 41 have a tapered shape such that the hole diameter thereof increases toward the lower side.

For the heat transmission portions 47, members are used that have a high heat conductivity, and that may be, for example, a thermosetting or thermoplastic adhesive agent, an adhesive sheet obtained by applying an adhesive agent to a base material, a heat discharging grease, a heat radiation gel, a heat conduction sheet, or the like. When an adhesive agent is used, a mixture of two types of epoxy adhesive agents that solidifies at room temperature may be used, for example. Alternatively, for example, an insulating film made of a synthetic resin to both surfaces of which an insulating adhesive agent is applied may be used. The heat transmission portion 47 is arranged overlapping, on its upper side, with at least a part of the electronic component 26, and heat of the electronic component 26 transmitted to the heat transmission portion 47 is discharged from the heat discharging member 28.

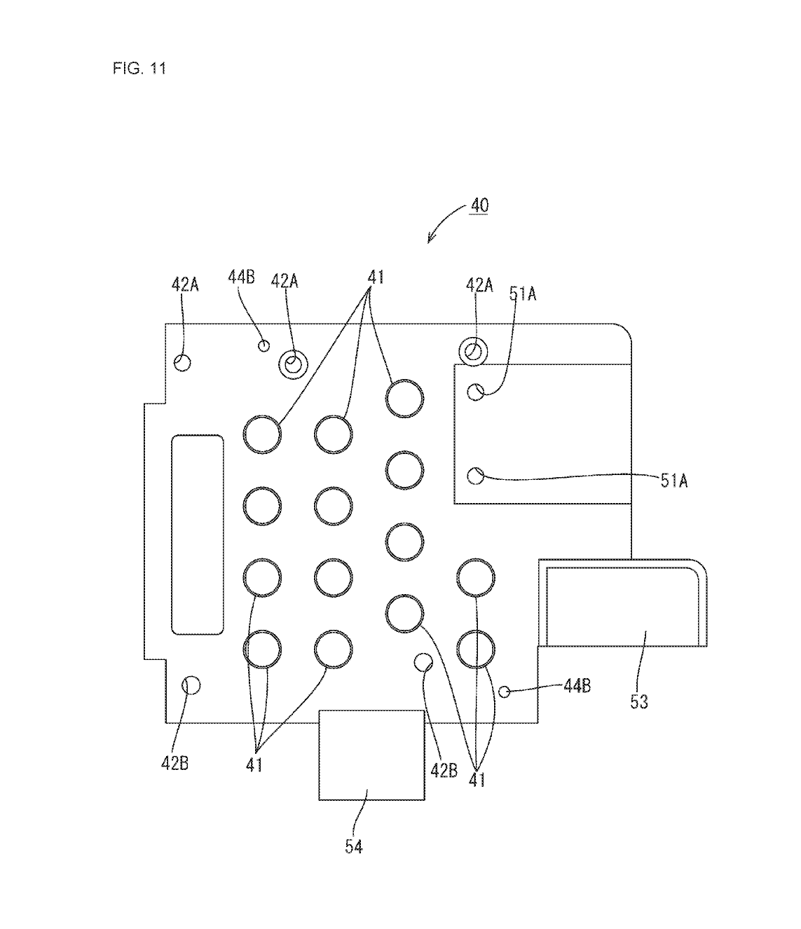

The screw passage holes 42A and 42B are formed at positions close to the peripheral edge of the spacer 40. The terminal passage hole 43 is formed through the spacer 40 in a rectangular shape. The positioning projections 44A and 44B are columnar, and are arranged at positions close to the corners on the peripheral edge of the spacer 40. The positioning projections 44A project upward from the upper surface of the spacer 40 in a columnar shape, and the positioning projections 44B project, as shown in FIG. 11, downward from the lower surface of the spacer 40 in a columnar shape.

The engaging projections 45 can engage with portions that are contiguous with the connector terminals 24. As shown in FIG. 7, the engaging projections 45 project upward in the vicinity of the rear side of the connector portion 54, and can be inserted into engaging holes 24A (see FIG. 5) of the circuit board 21. Accordingly, the engaging projections 45 receive a force that acts on the connector terminals 24 when the connector portion 54 is engaged with a counterpart connector (not shown), so that the force at the time of the engagement is unlikely to act on the circuit unit 20A.

As shown in FIG. 6, the extended portion 49 is provided with a flat extended portion 50 that is plate-shaped and is contiguous with the main portion 40A in a coplanar manner, and a plurality of accommodating portions 51 to 54 that accommodate a part of the circuit unit 20A. The accommodating portions 51 to 54 include nut accommodating portions 51 that accommodate nuts 39, a coil accommodating portion 52 that accommodates the coil 27, a terminal accommodating portion 53 that accommodates the stud bolt 56 serving as an external connection terminal, and a connector portion 54 that accommodates the connector terminals 24.

The nut accommodating portions 51 are formed as recesses formed in the flat extended portion 50, and have a shape that corresponds to the rectangular nuts 39 so as to prevent the nuts 39 from rotating. Each nut accommodating portion 51 has, on the bottom surface thereof, a hole 51A that is formed through the flat extended portion 50, and whose diameter is reduced stepwise, so that the front end of the screw 38 can be passed therethrough.

The coil accommodating portion 52 has a bottom portion 52A that is recessed further downward than the flat extended portion 50, and a wall portion 52B that has the shape of a rectangular tube that encloses the entire periphery of the coil 27. The bottom portion 52A is fitted into the recess 32A of the heat discharging member 28. The wall portion 52B has substantially the same height as the coil 27 accommodated in the coil accommodating portion 52. The wall portion 52B is divided at positions from which the coil wire 27B is drawn.

As shown in FIG. 4, the terminal accommodating portion 53 accommodates a plate-shaped rectangular base portion 56B of the stud bolt 56, which includes the base portion 56B and a columnar pillar portion 56A, the terminal portion 25A, and a metal connection plate 55. Specifically, the terminal accommodating portion 53 has accommodating recesses 53B into which the base portion 56B can be inserted from the front side while sliding to a predetermined position, and cut-out portions 53A into which the pillar portion 56A can be inserted. The connection plate 55 is rectangular, and has a bolt hole 55A that is formed through the connection plate 55, and into which the pillar portion 56A of the stud bolt 56 can be inserted, and one side in a longitudinal direction of the connection plate 55 is placed on the terminal portion 25A.

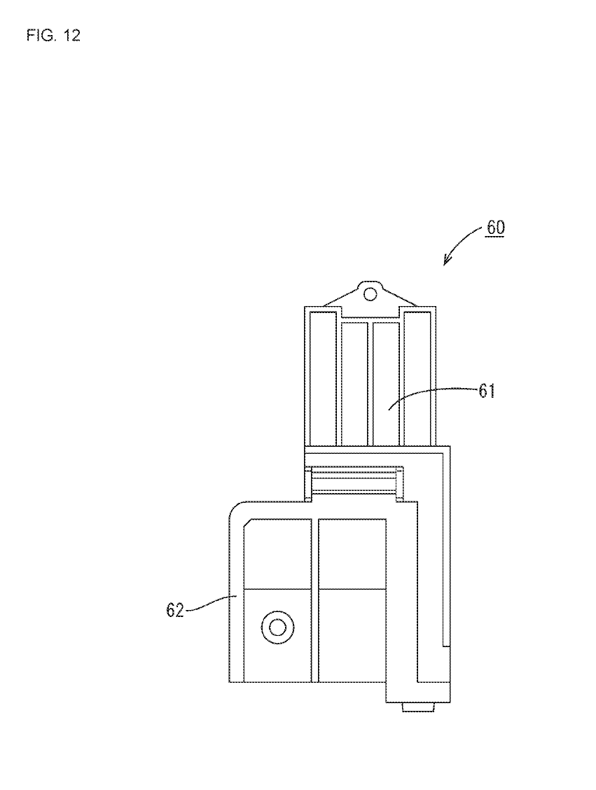

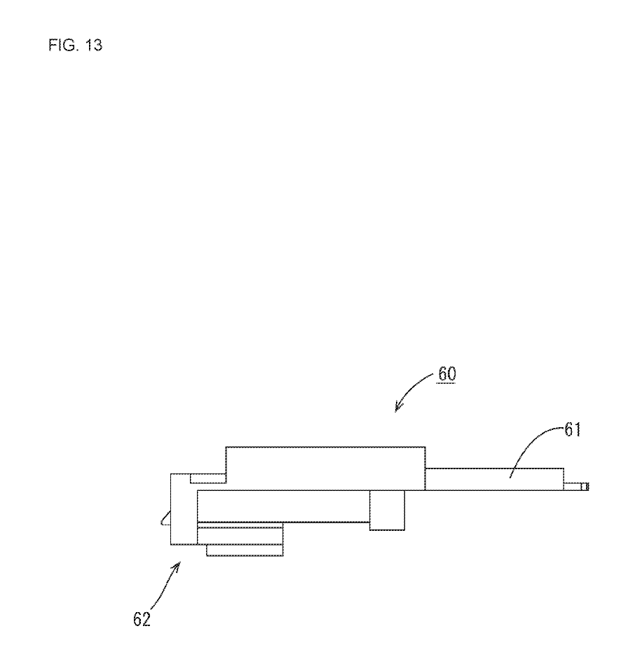

A separate auxiliary member 60 is arranged in the vicinity of the coil accommodating portion 52 and the terminal accommodating portion 53. As shown in FIGS. 12 and 13, the auxiliary member 60 includes a lid 61 that covers the coil accommodating portion 52, and a box body 62 that is arranged around the terminal accommodating portion 53 to form the box portion 16.

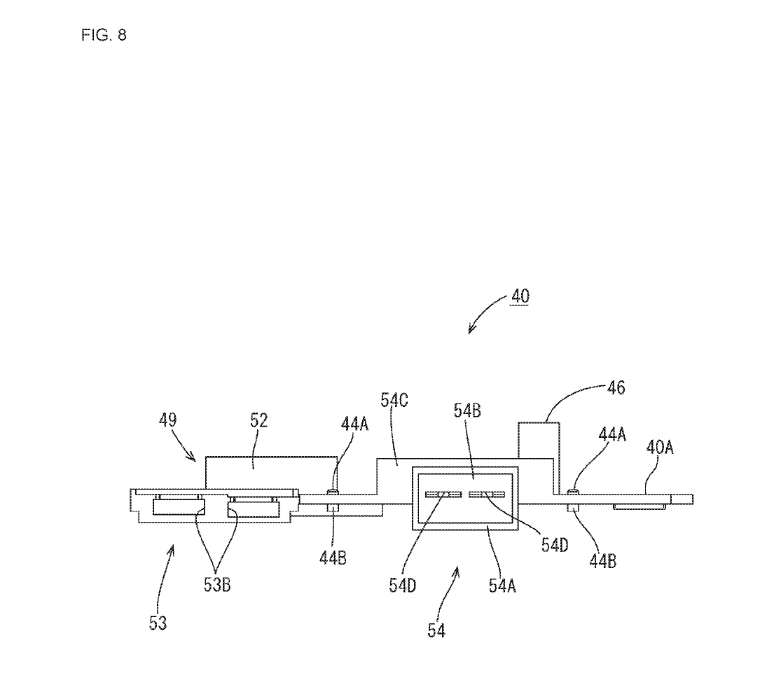

As shown in FIG. 8, the connector portion 54 is a connector housing that includes a hood portion 54A that encloses the connector terminals 24, and a rear wall portion 54B that closes the hood portion 54A. The rear wall portion 54B has terminal insertion holes 54D that are formed through the rear wall portion 54B, and into which the connector terminals 24 are inserted. A flange 54C that extends along the peripheral edge of the main portion 40A protrudes from the connector portion 54.

As shown in FIG. 6, the spacer 40 includes, on the peripheral edge thereof, a thick-walled portion 40B that has a large thickness on the upper surface side, and a band-shaped protruding piece 46 that is raised upward. The spacer 40 is made of an insulating plastic (synthetic resin), and is formed in one piece as a whole by injecting the synthetic resin into a mold. In other words, the spacer 40 employs a material that has such a strength that it does not easily deform due to a force acting at the time of tightening the screws 48.

The following will describe a method for manufacturing the circuit assembly 20 and the electrical junction box 10.

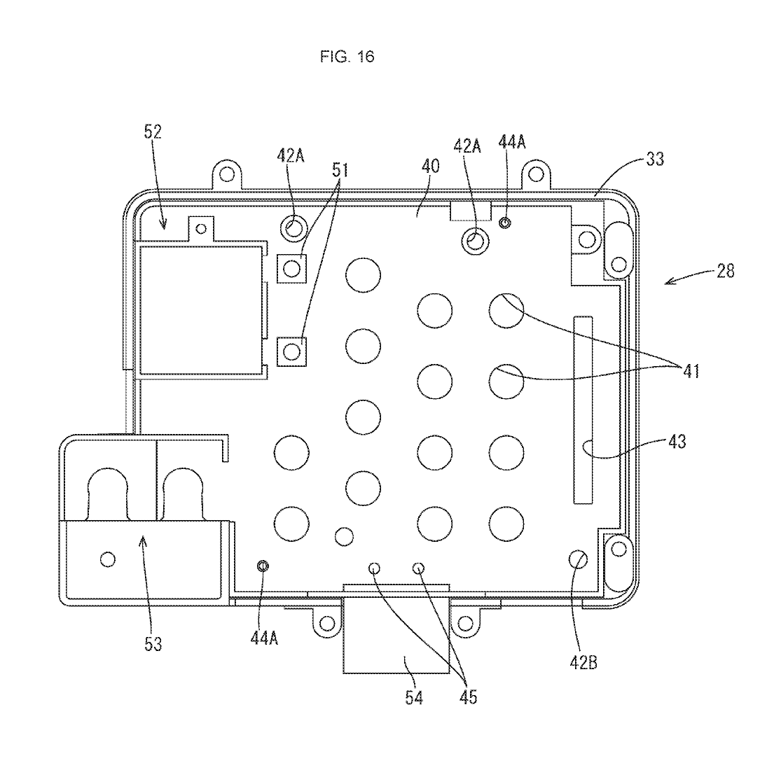

The spacer 40 is mounted on the mounting portion 29 that is the upper surface of the heat discharging member 28 (FIG. 16). Then, the nuts 39 are accommodated in the nut accommodating portions 51, and an adhesive agent is applied into the through holes 41 of the spacer 40.

Solder paste is added to the electrically conducting path of the circuit board 21 that is obtained by adhering the printed board 21A and the busbar board 21B to each other using an adhesive member, the electronic components 26 are arranged at predetermined positions, and the resulting object is passed through a reflow furnace to be subjected to reflow soldering. Thereby, the circuit unit 20A in which the electronic components 26 are mounted on the circuit board 21 is achieved.

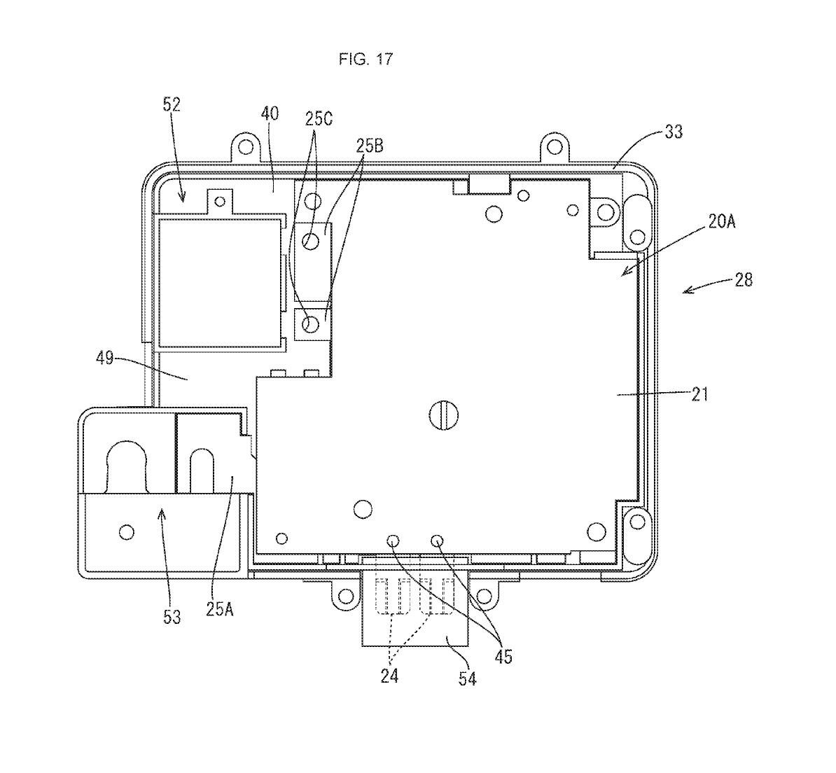

Then, by inserting the connector terminals 24 of the circuit unit 20A into the terminal insertion holes 54D of the connector portion 54, the circuit unit 20A is mounted on the spacer 40 (FIG. 17).

Then, the coil 27 is accommodated in the coil accommodating portion 52, and the ends of the coil wire 27B and the terminal portions 25B of the circuit unit 20A are fastened to each other with the screws 38 and the nuts 39. Furthermore, the stud bolt 56 is accommodated in the terminal accommodating portion 53, and the connection plate 55 is mounted. Furthermore, the screws 48 are inserted into the screw holes 22, the screw passage holes 42A and 42B, and the screw holes 31A, and are screwed to fix the circuit board 21 and the heat discharging member 28 to each other, thereby achieving the circuit assembly 20 (see FIG. 3). The shield cover 11 is placed onto the circuit assembly 20 and the screws 13 are screwed, thereby achieving the electrical junction box 10 (FIG. 1).

According to the present embodiment, the following functions and effects can be attained.

According to the present embodiment, since the main portion 40A of the spacer 40 is disposed between the circuit unit 20A and the heat discharging member 28, it is possible to keep the distance between the circuit unit 20A and the heat discharging member 28 constant without using a jig. Furthermore, since the accommodating portions 51 to 54 of the spacer 40 accommodate a part (the nuts 39, the coil 27, the stud bolt 56, and the connector terminals 24) of the circuit unit 20A, it is possible to hold parts of the circuit unit 20A at predetermined positions using the structure of the spacer 40, instead of providing a separate frame-shaped resin member for accommodating parts of the circuit unit 20A. Accordingly, it is possible to hold parts of the circuit unit 20A at predetermined positions while keeping the distance between the circuit board 21 and the heat discharging member 28 constant, with a simple configuration.

Furthermore, the main portion 40A and the accommodating portions 51 to 54 are molded in one piece using a resin.

With this, it is possible to simplify the configuration compared to a case where, for example, a separate accommodating portion is fixed to the main portion 40A to form a spacer.

Furthermore, the accommodating portions 51 to 54 accommodate the nuts 39 of the circuit unit 20A.

With this, by providing the nut accommodating portions 51 obtained by reducing the thickness of the spacer 40 locally, it is possible to hold the nuts 39 in positions, and thus it is possible to simply the configuration for holding the nuts 39 in positions.

Furthermore, the main portion 40A is provided with through holes 41 that are formed through the main portion 40A, and heat transmission portions 47 that are arranged in the through holes 41, and are configured to transmit heat of the circuit unit 20A to the heat discharging member 28.

With this, the heat transmission portions 47 allow heat of the circuit unit 20A to be discharged from the heat discharging member 28.

Furthermore, the circuit unit 20A and the heat discharging member 28 are fastened to each other with screws 48.

With this, the circuit unit 20A and the heat discharging member 28 can be fixed to each other firmly with the screws 48, while the spacer 40 receives a force acting when the circuit unit 20A and the heat discharging member 28 are fastened to each other with the screws.

### OTHER EMBODIMENTS

The present invention is not limited to the embodiment explained in the foregoing description given with reference to the drawings, and the technical scope of the present invention encompasses, for example, the following embodiments.

(1) The parts of the circuit unit 20A that are accommodated by the spacer 40 are not limited to the above-described nuts 39, coil 27, stud bolt 56, and connector terminals 24, and may be other components of the circuit unit.

(2) The material of the heat discharging member 28 is not limited to aluminum or an aluminum alloy, and may be any material as long as it is a metal material that has high heat conductivity. For example, the heat discharging member 28 may be made of copper or a copper alloy.

(3) Although the circuit unit 20A and the heat discharging member 28 are fastened to each other with the screws 48, the circuit unit 20A and the heat discharging member 28 may be fixed to each other using a fixation means (for example, a lock mechanism) other than the screws.

1. A circuit assembly comprising:
a circuit unit that includes an electrically conducting path on which electronic components are mounted;
a heat discharging member that is placed on the circuit unit, and is configured to discharge heat of the circuit unit; and
a spacer that is disposed between the circuit unit and the heat discharging member,
wherein the spacer is provided with a main portion that is disposed between the circuit unit and the heat discharging member, and an accommodating portion that accommodates a part of the circuit unit, and
the main portion is provided with a through hole that is formed through the main portion, and a heat transmission portion that is arranged in the through hole, and is configured to transmit heat of the circuit unit to the heat discharging member.

2. The circuit assembly according to claim 1,
wherein the main portion and the accommodating portion are molded in one piece using a resin.

3. The circuit assembly according to claim 1,
wherein the accommodating portion accommodates an external connection terminal of the circuit unit.

4. The circuit assembly according to claim 1,
wherein the accommodating portion accommodates a coil of the circuit unit.

5. The circuit assembly according to claim 1,
wherein the accommodating portion accommodates a nut of the circuit unit.

6. (canceled)

7. The circuit assembly according claim 1,
wherein the circuit unit and the heat discharging member are fastened to each other with screws.

8. An electrical junction box provided with the circuit assembly according to claim 1.
